(19) United States
(12) Patent Application Publication
(10) Pub. No.: US 2024/0038645 A1
(43) Pub. Date: Feb. 1, 2024

(54) Semiconductor Package Interconnection Structure

(71) Applicant: Avago Technologies International Sales Pte. Limited, Singapore (SG)

(72) Inventors: Sam Zhao, Irvine, CA (US); Sam Karikalan, Ladera Ranch, CA (US); Mayank Mayukh, Fort Collins, CO (US); Reza Sharifi, Irvine, CA (US); Liming Tsau, Irvine, CA (US); Roger Fratti, Mohnton, PA (US); Arun Ramakrishnan, Lake Forest, CA (US); Dharmendra Saraswat, Foothill Ranch, CA (US)

(21) Appl. No.: 17/873,521

(22) Filed: Jul. 26, 2022

(51) Int. Cl. H01L 23/498; H01L 21/48

(52) U.S. Cl. CPC H01L 23/49816; H01L 21/4853; H01L 21/4857; H01L 21/486; H01L 23/49822; H01L 23/49833; H01L 23/49838; H01L 24/16

(57) ABSTRACT

Novel tools and techniques are provided for implementing novel semiconductor package interconnection structure(s) between package substrate and PCB. In various embodiments, a semiconductor device comprises: a substrate; a plurality of posts; a plurality of solder anchor portions; and a plurality of solder balls. Each post is coupled at a proximal end to a conductive point on a layer of the substrate, and has a length extending along its axis between its proximal and distal ends and a width orthogonal to the length. Each solder anchor portion is coupled to the distal end of a corresponding post, and has a width that is larger than the width of a distal end of a pillar portion of the corresponding post. Each solder ball is disposed on and around a corresponding solder anchor portion, the solder balls and corresponding posts forming conductive interconnects between corresponding substrate conductive points and corresponding PCB contact points.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to methods and apparatuses for implementing semiconductor technology, and, more particularly, to methods and apparatuses for implementing a novel semiconductor package interconnection structure(s) between a package substrate and a printed circuit board (“PCB”) on which the package substrate is mounted.

### BACKGROUND

Conventional Ball Grid Array (“BGA”) packages have spherical or hemispherical solder balls mounted on metal pads or ball pads exposed on a substrate surface. These substrate ball pads are typically covered partially under a solder mask layer with a center region of the ball pads exposed to receive solder balls. With increasing input/output (“I/O”) density, it is desirable to reduce solder ball pitch and size. However, smaller ball pitch and ball size can cause higher thermomechanical stresses on the solder joints due to reduced substrate stand-off height, which is the space between the package substrate and the PCB on which the BGA package is surface mounted. High thermomechanical stresses on solder joints connecting the BGA package substrate and the PCB have been known to cause mechanical failures of the solder joints, which lead to open circuit failures of electrical interconnection.

For conventional BGA packages, to reduce solder joint thermomechanical stresses, larger size solder balls can be used on BGA packages due to larger stand-off height offered by larger solder balls. However, larger ball size leads to larger ball pitch and lower I/O density for BGA packages.

Hence, there is a need for more robust and scalable solutions for implementing semiconductor technology, and, more particularly, for implementing a novel semiconductor package interconnection structure(s) between a package substrate and a PCB on which the package substrate is mounted.

### SUMMARY

The techniques of this disclosure generally relate to tools and techniques for implementing semiconductor technology, and, more particularly, to methods and apparatuses for implementing a novel semiconductor package interconnection structure(s) between a package substrate and a PCB on which the package substrate is mounted.

In an aspect, a semiconductor device comprises: a package substrate comprising one or more layers; a plurality of posts; and a plurality of solder balls. In some cases, each post comprises a proximal end, a pillar portion, a distal end, and a solder anchor portion, each post being coupled at the proximal end to a conductive point on a layer among the one or more layers of the package substrate, each pillar portion having a length extending along its axis between the proximal end and the distal end and a width at the distal end that is orthogonal to the length, each solder anchor portion being coupled to the distal end of a corresponding post, wherein each solder anchor portion has a width that is larger than the width of the distal end of the pillar portion to which it is coupled. In some instances, each solder ball is disposed on and around the solder anchor portion of a corresponding post, one or more solder balls among the plurality of solder balls and corresponding one or more posts among the plurality of posts forming conductive interconnects between corresponding conductive points on the package substrate and corresponding contact points on a PCB.

In some embodiments, the conductive points on the package substrate comprise a plurality of conductive pads, each conductive pad being coupled to the proximal end of a corresponding post among the plurality of posts.

According to some embodiments, the plurality of posts is formed on the plurality of conductive pads using semiconductor package manufacturing processes comprising at least one of one or more photoresist film application processes, one or more image transfer processes, one or more pattern transfer processes, one or more material plating processes, one or more photoresist film stripping processes, or one or more reflow processes, and/or the like. In some cases, the plurality of posts is formed on the package substrate extending from a bottom layer of the package substrate, such that the plurality of solder balls is formed by forming a solder shell around the solder anchor portion of each post.

Alternatively, the plurality of posts is formed on the plurality of conductive pads using wire bonding processes. In some cases, the plurality of posts is formed on the package substrate extending from a bottom layer of the package substrate, such that the plurality of solder balls is formed by applying molten solder material to the solder anchor portion of each post.

In some embodiments, the solder anchor portion has a shape comprising one of a sphere, an ellipsoid, a hemisphere, a cylinder, a cone, a truncated cone, a triangular prism, a cube, a rectangular prism, a pentagonal prism, a hexagonal prism, an octagonal prism, or other three-dimensional polygon, or the like. In some instances, one or more posts among the plurality of posts are formed through two or more substrate layers among the one or more layers of the package substrate, wherein a cross-section of each of the one or more posts is continuous as it extends through the two or more substrate layers, without geometrical transitions in the cross-section of each post that exceeds a proportion of a width of the cross-section as each post extends between adjacent substrate layers among the two or more substrate layers. In some cases, the cross-section of each of the one or more posts is one of the same within a threshold amount of deviation of 10%, continuously expanding, or continuously contracting, or the like, as it extends through the two or more substrate layers.

According to some embodiments, two or more posts among the plurality of posts are connected to each other via one or more cross bars.

In some embodiments, the length of the pillar portion of each of the plurality of posts is different from that of one or more adjacent posts, wherein the length of the pillar portion of each post is based on heights of corresponding contact points on the PCB and is not solely based on warpage of the package substrate, wherein the heights of the corresponding contact points on the PCB are determined based on a scan of a surface of the PCB.

In another aspect, a method comprises: forming a plurality of posts on a package substrate, the package substrate comprising one or more layers, each post comprising a proximal end, a pillar portion, and a distal end, each post being coupled at the proximal end to a conductive point on a layer among the one or more layers of the package substrate, each pillar portion having a length extending along its axis between the proximal end and the distal end and a width at the distal end that is orthogonal to the length; and forming a solder anchor portion on the distal end of each post, wherein each solder anchor portion has a width that is larger than the width of the distal end of the pillar portion to which it is coupled.

In some embodiments, the method further comprises forming a plurality of solder balls each on and around the solder anchor portion of a corresponding post, one or more solder balls among the plurality of solder balls and corresponding one or more posts among the plurality of posts forming conductive interconnects between corresponding conductive points on the package substrate and corresponding contact points on a PCB.

In some instances, the package substrate comprises a first layer, a second layer, a plurality of conductive pads that is formed between the first layer and the second layer, and a third layer that is formed on or over the second layer. In some cases, forming the plurality of posts on the package substrate comprises: forming a plurality of first openings in the second layer and the third layer, thereby exposing a portion of each of the plurality of conductive pads, wherein a width of each opening defines the width of the pillar portion; and forming the pillar portion of each post within one of the plurality of first openings. In some instances, forming the solder anchor portion on the distal end of each post comprises: forming a fourth layer on or over the third layer and the pillar portions of the plurality of posts; forming a plurality of second openings in the fourth layer, each of the plurality of second openings having a width that is greater than the width of the distal end of the pillar portion and being centered on the pillar portion of a corresponding post; and forming the solder anchor portion for each post within one of the plurality of second openings.

In some cases, forming the plurality of solder balls each on and around the solder anchor portion of the corresponding post comprises: forming a fifth layer on or over the fourth layer and the solder anchor portion for each post; forming a plurality of third openings in the fifth layer and in the fourth layer, each of the plurality of third openings having a width that is greater than the width of the solder anchor portion and being centered on the solder anchor portion; forming a solder shell for each post within one of the plurality of third openings, such that each solder shell covers a distal portion and side portions of the corresponding solder anchor portion for each post; removing the third, fourth, and fifth layers; and performing a reflow to melt the solder shell thereby forming the plurality of solder balls disposed on corresponding plurality of solder anchors.

In some instances, the plurality of posts is formed on the plurality of conductive pads using semiconductor package manufacturing processes comprising at least one of one or more photoresist film application processes, one or more image transfer processes, one or more pattern transfer processes, one or more material plating processes, one or more photoresist film stripping processes, or one or more reflow processes, and/or the like.

According to some embodiments, the package substrate comprises a first layer, a second layer, and a plurality of conductive pads that is formed between the first layer and the second layer, wherein a plurality of openings is formed in the second layer thereby exposing a portion of each of the plurality of conductive pads. In some cases, forming the plurality of posts on the package substrate comprises: using wire bonding to affix each post to an exposed portion of a corresponding one of the plurality of conductive pads; and breaking each post to a respective determined length of the pillar portion of the post. In some instances, forming the solder anchor portion on the distal end of each post comprises: forming a ball tip as the solder anchor portion at the distal end of each post.

In some cases, forming the plurality of solder balls each on and around the solder anchor portion of each post comprises: lowering the package substrate such that the ball tip for each post is dipped into one of a partitioned portion of a tray of molten solder material or a pool of molten solder material, during solder reflow; and lifting the package substrate away from the one of the partitioned portion of the tray of molten solder material or the pool of molten solder material.

In some instances, the method further comprises: determining heights of contact points on the PCB based on a scan of a surface of the PCB. In some cases, the length of the pillar portion of each post is determined based on the determined heights of corresponding contact points on the PCB. In some instances, the length of the pillar portion of each of the plurality of posts is different from that of one or more adjacent posts.

In yet another aspect, a semiconductor device comprises: a package substrate comprising one or more bottom layers; a plurality of posts; a solder anchor portion; and a plurality of solder balls. In some cases, each post comprises a proximal end, a pillar portion, and a distal end, each post being coupled at the proximal end to a conductive point on a bottom layer among the one or more bottom layers of the package substrate, each pillar portion having a length extending along its axis between the proximal end and the distal end and a width at a distal end thereof that is orthogonal to the length. In some instances, each solder anchor portion is coupled to the distal end of a corresponding post among the plurality of posts, wherein each solder anchor portion has a width that is larger than the width of the distal end of the pillar portion to which it is coupled. In some cases, each solder ball is disposed on and around the solder anchor portion of a corresponding post, one or more solder balls among the plurality of solder balls and corresponding one or more posts among the plurality of posts forming conductive interconnects between corresponding conductive points on the package substrate and corresponding contact points on a PCB. In some instances, the length of the pillar portion of each of the plurality of posts is different from that of one or more adjacent posts, wherein the length of the pillar portion of each post is based on heights of corresponding contact points on the PCB and is not solely based on warpage of the package substrate, wherein the heights of the corresponding contact points on the PCB are determined based on a scan of a surface of the PCB.

Various modifications and additions can be made to the embodiments discussed without departing from the scope of the invention. For example, while the embodiments described above refer to particular features, the scope of this invention also includes embodiments having different combination of features and embodiments that do not include all of the above-described features.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIGS. 1A and 1B are schematic diagrams illustrating various non-limiting examples of a semiconductor device with a novel semiconductor package interconnection structure(s) between a package substrate and a PCB on which the package substrate is to be mounted, in accordance with various embodiments.

FIGS. 2A-2P are schematic diagrams illustrating various non-limiting examples of semiconductor package manufacturing processes for forming various examples of a semiconductor device with a novel semiconductor package interconnection structure(s) between a package substrate and a PCB on which the package substrate is to be mounted, in accordance with various embodiments.

FIGS. 3A-3O are schematic diagrams illustrating various non-limiting examples of wire bonding-based processes for forming various examples of a semiconductor device with a novel semiconductor package interconnection structure(s) between a package substrate and a PCB on which the package substrate is to be mounted, in accordance with various embodiments.

FIGS. 4A-4G are flow diagrams illustrating a method for forming a semiconductor device with a novel semiconductor package interconnection structure(s) between a package substrate and a PCB on which the package substrate is to be mounted, in accordance with various embodiments.

### DETAILED DESCRIPTION

Overview

Various embodiments provide tools and techniques for implementing semiconductor technology, and, more particularly, to methods and apparatuses for implementing a novel semiconductor package interconnection structure(s) between a package substrate and a PCB on which the package substrate is mounted.

In various embodiments, a semiconductor device comprises: a package substrate comprising one or more layers; a plurality of posts; a plurality of solder anchor portions; and a plurality of solder balls. In some cases, each post comprises a proximal end, a pillar portion, and a distal end, each post being coupled at the proximal end to a conductive point on a layer among the one or more layers of the package substrate, each pillar portion having a length extending along its axis between the proximal end and the distal end and a width at the distal end that is orthogonal to the length. Each solder anchor portion is coupled to the distal end of a corresponding post, each solder anchor portion having a width that is larger than the width of the distal end of the pillar portion to which it is coupled. In some instances, each solder ball is disposed on and around the solder anchor portion of a corresponding post, one or more solder balls among the plurality of solder balls and corresponding one or more posts among the plurality of posts forming conductive interconnects between corresponding conductive points on the package substrate and corresponding contact points on a PCB.

In the various aspects described herein, a novel semiconductor package interconnection structure(s) between a package substrate and a PCB on which the package substrate is mounted is provided. This allows for an increased stand-off height H, defined by a distance between a proximal end of the post and a distal end of a solder ball that is disposed on a solder anchor portion attached to the distal end of the post. With such a structure, smaller solder balls (i.e., with smaller widths W) may be achieved to enable an increased stand-off height H, thereby allowing for greater density of components due to decreased pitch, which is defined by a distance between a center of one I/O or post and that of an adjacent or neighboring I/O or post.

These and other aspects of the package substrate, semiconductor package, and method for implementing a novel semiconductor package interconnection structure(s) between a package substrate and a PCB on which the package substrate is mounted are described in greater detail with respect to the figures.

The following detailed description illustrates a few embodiments in further detail to enable one of skill in the art to practice such embodiments. The described examples are provided for illustrative purposes and are not intended to limit the scope of the invention.

In the following description, for the purposes of explanation, numerous details are set forth in order to provide a thorough understanding of the described embodiments. It will be apparent to one skilled in the art, however, that other embodiments of the present invention may be practiced without some of these details. In other instances, some structures and devices are shown in block diagram form. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

Unless otherwise indicated, all numbers used herein to express quantities, dimensions, and so forth used should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically stated otherwise.

### Some Embodiments

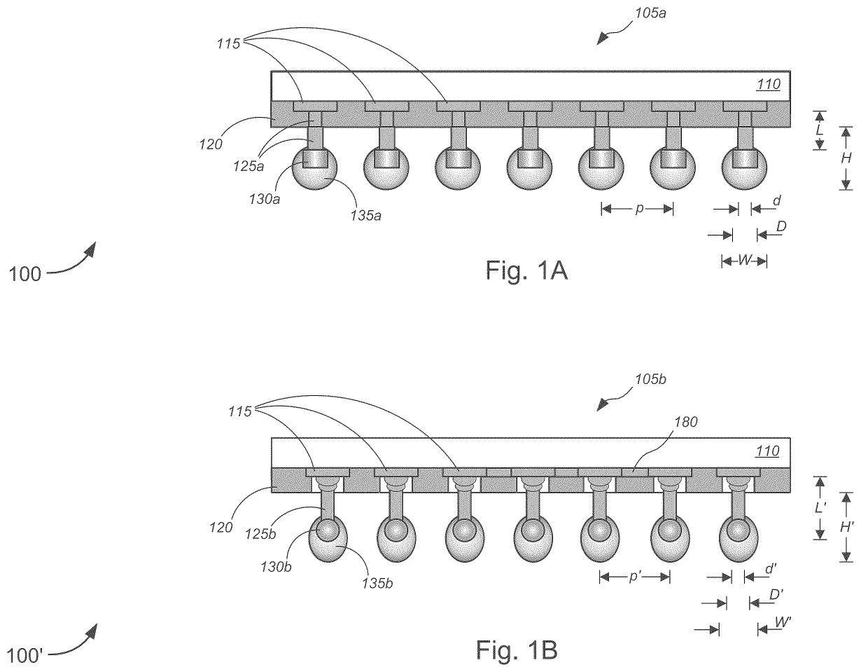

We now turn to the embodiments as illustrated by the drawings. FIGS. 1-4 illustrate some of the features of the method, system, and apparatus for implementing semiconductor technology, and, more particularly, to methods and apparatuses for implementing a novel semiconductor package interconnection structure(s) between a package substrate and a printed circuit board (“PCB”) on which the package substrate is mounted, as referred to above. The methods and apparatuses illustrated by FIGS. 1-4 refer to examples of different embodiments that include various components and steps, which can be considered alternatives or which can be used in conjunction with one another in the various embodiments. The description of the illustrated methods and apparatuses shown in FIGS. 1-4 is provided for purposes of illustration and should not be considered to limit the scope of the different embodiments.

When an element is referred to herein as being “connected” or “coupled” to another element, it is to be understood that the elements can be directly connected to the other element, or have intervening elements present between the elements. In contrast, when an element is referred to as being “directly connected” or “directly coupled” to another element, it should be understood that no intervening elements are present in the “direct” connection between the elements. However, the existence of a direct connection does not exclude other connections, in which intervening elements may be present.

Similarly, when an element is referred to herein as being “bonded” to another element, it is to be understood that the elements can be directly bonded to the other element (without any intervening elements) or have intervening elements present between the bonded elements. In contrast, when an element is referred to as being “directly bonded” to another element, it should be understood that no intervening elements are present in the “direct” bond between the elements. However, direct bonding does not exclude other forms of bonding, in which intervening elements may be present.

Likewise, when an element is a layer, it is to be understood that such element can be a single layer or a series of multiple layers. When described in relation to other layers among a plurality of layers, such element can be said to be directly connected to another layer among the plurality of layers or have intervening elements or layers present between the element and the another layer. In contrast, when the element is referred to as being “directly connected” or “directly coupled” to another layer, it should be understood that no intervening elements or layers are present in the “direct” connection between the element and the another layer. However, the existence of a direct connection does not exclude other connections, in which intervening elements or layers may be present.

When an element is described as being “on” or disposed “on” another element, it is to be understood that such element can be said to be directly on (or disposed on) the another element or have intervening elements or layers present between the element and the another element. In contrast, when the element is referred to as being “directly on” or “directly disposed on” another element, it should be understood that no intervening elements or layers are present in the “direct” connection between the element and the another element. However, the existence of a direct connection does not exclude other connections, in which intervening elements or layers may be present.

With reference to the figures, FIGS. 1A and 1B (collectively, “FIG. 1”) are schematic diagrams illustrating various non-limiting examples 100 and 100′ of a semiconductor device with a novel semiconductor package interconnection structure(s) between a package substrate and a PCB on which the package substrate is to be mounted, in accordance with various embodiments.

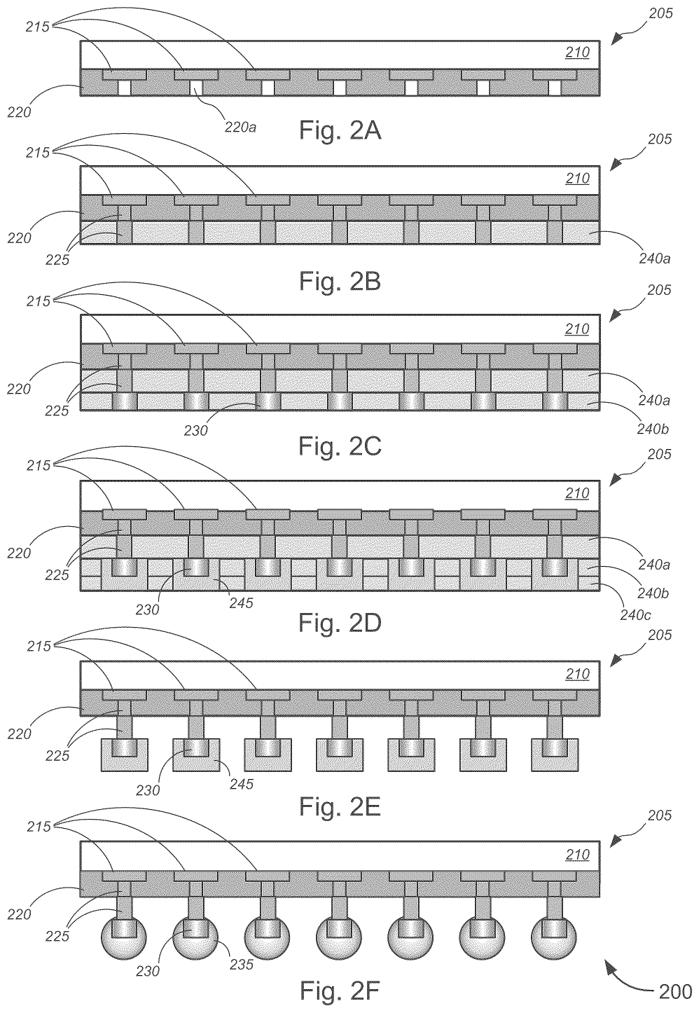

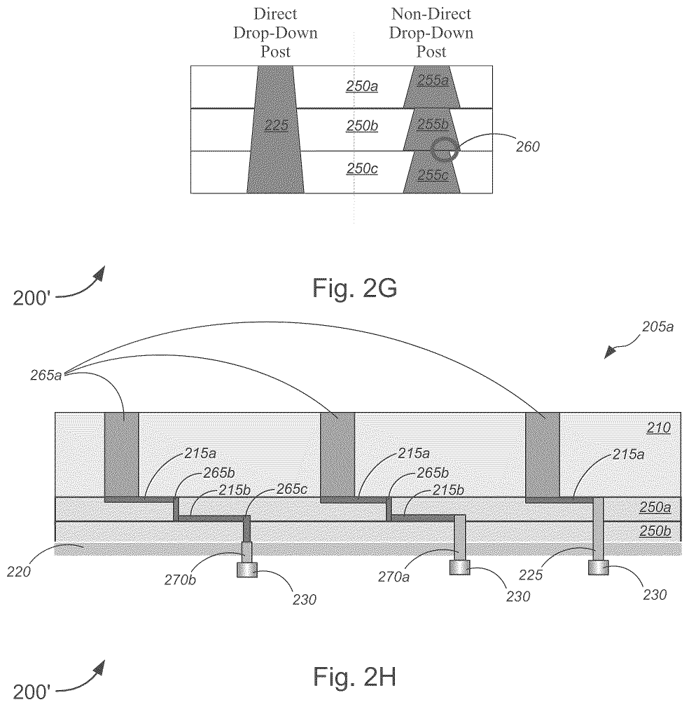

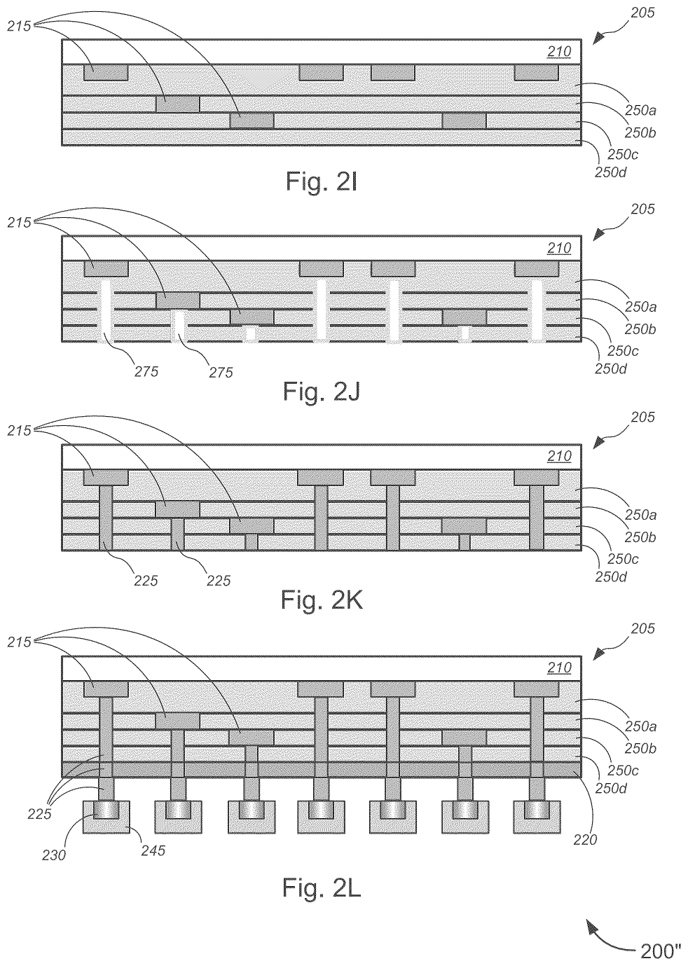

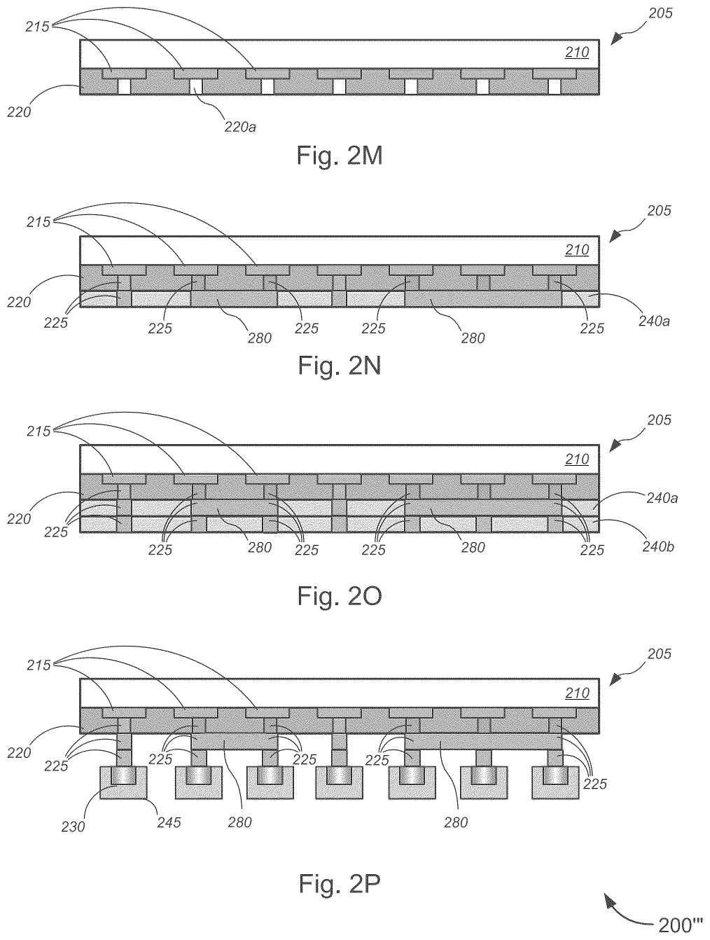

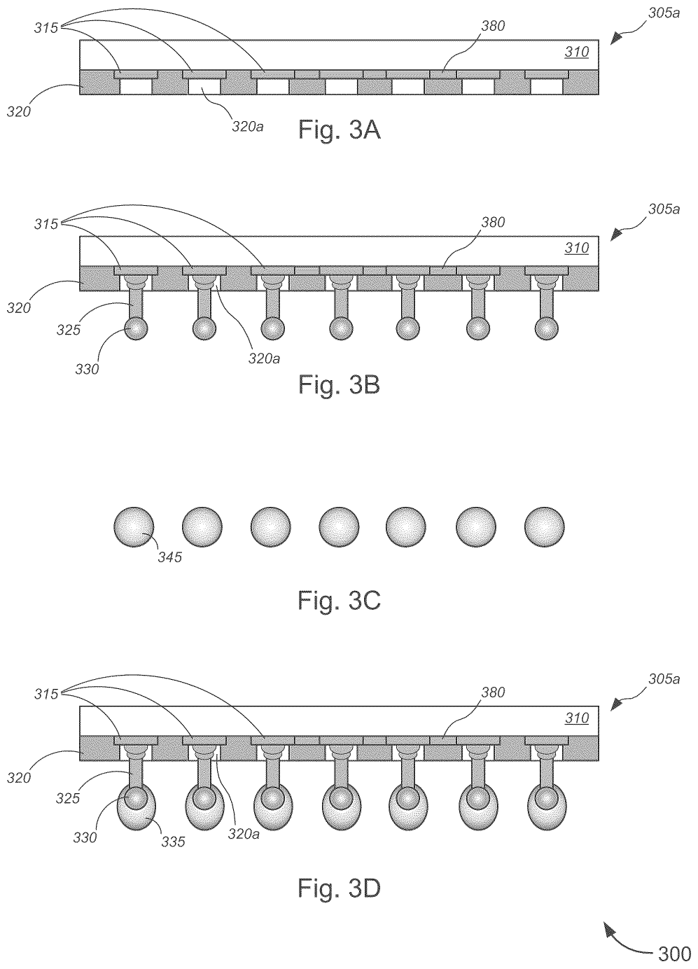

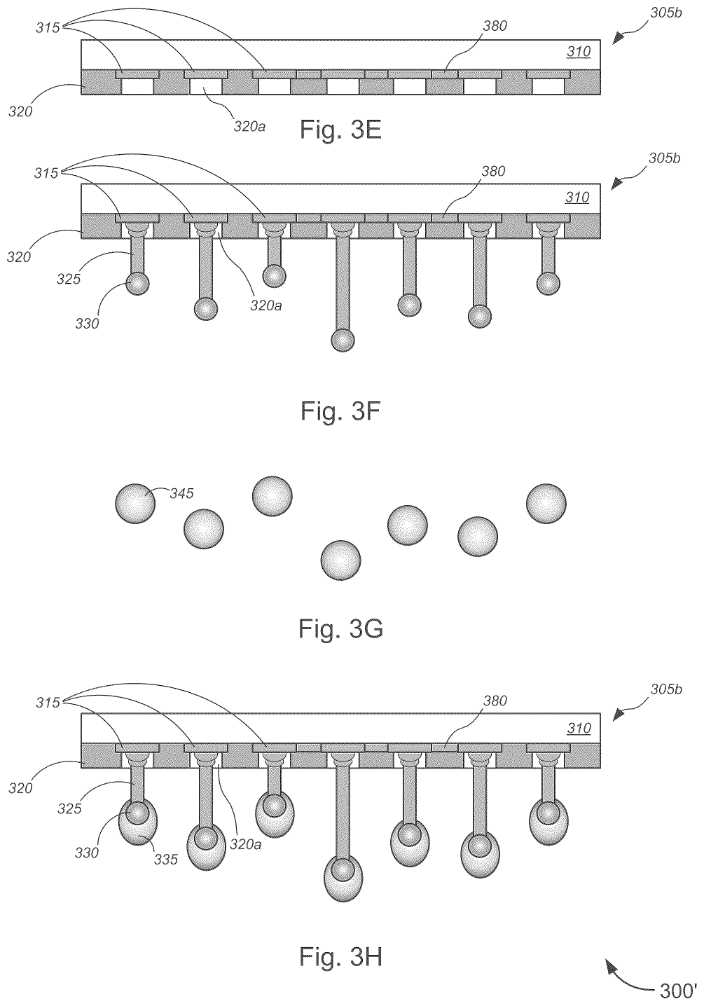

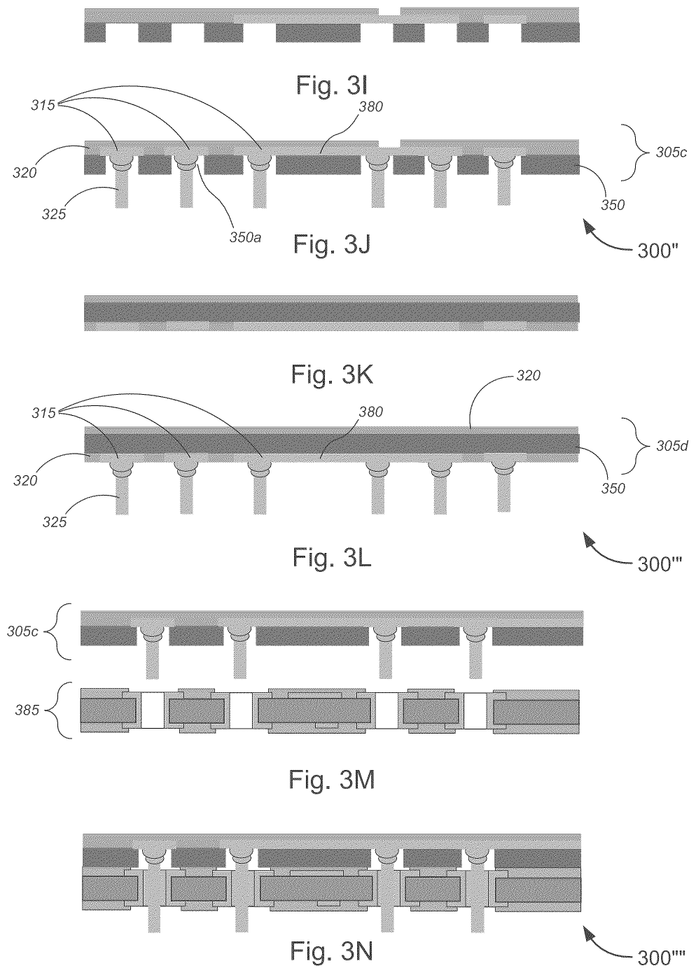

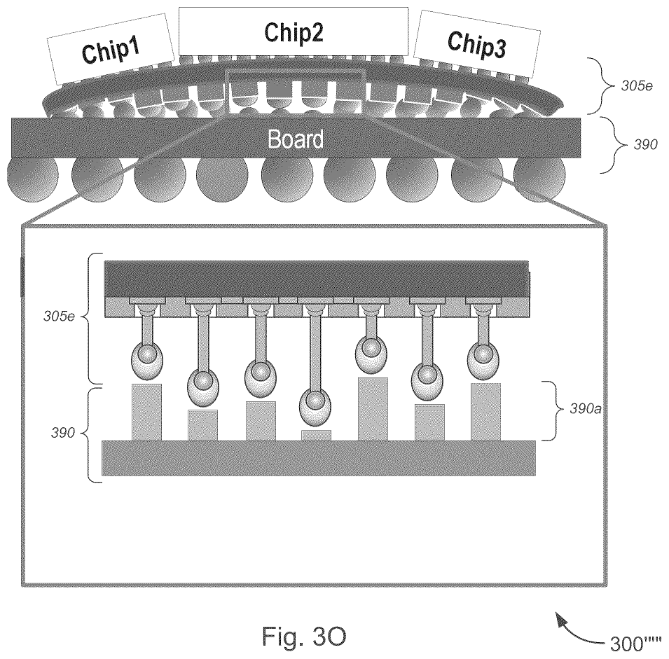

As shown in the non-limiting examples 100 and 100′ of FIGS. 1A and 1B, respectively, a semiconductor device or package 105a or 105b includes, without limitation, a package substrate 110, a plurality of contact pads 115 (also referred to as “conductive points” or “conductive pads” or the like), a solder mask layer 120, a plurality of posts 125a or 125b, a plurality of solder anchor portions 130a or 130b, and a plurality of solder balls 135a or 135b, and/or the like. The semiconductor device or package 105a of FIG. 1A is formed using semiconductor package manufacturing processes including, but not limited to, at least one of one or more photoresist film (also known as “dry film” or the like) application processes, one or more image transfer processes, one or more pattern transfer processes, one or more material plating processes, one or more photoresist film stripping processes, or one or more reflow processes, and/or the like, aspects of which are shown and described below with respect to FIGS. 2A-2P. The semiconductor device or package 105b of FIG. 1B, on the other hand, is formed using wire bonding or wire bonding-based processes, aspects of which are shown and described below with respect to FIGS. 3A-3O.

Dry film photoresist or dry film resist is a type of photopolymeric photoresist material that is used for substrates of semiconductor packages or for PCB manufacturing. Liquid photopolymeric photoresist, or liquid photoresist, is typically used on silicon wafers or silicon substrates for semiconductor chip manufacturing. In some instances, the one or more photoresist film application processes (for dry film photoresist) may include, but are not limited to, a dry film lamination process(es) (in which the dry film photoresist, which is in the form of an already manufactured solvent-free (or solvent-poor) film that is available in rolls, is applied to the substrate while the substrate is being moved (on a substrate carrier) between heated rolls that apply pressure to laminate the dry film photoresist onto the substrate, or the like), or the like. In some cases, particularly where a conductive material may be required for subsequent plating processes, a thin copper layer may first be applied, plated (e.g., using chemical plating, electro-less plating, or the like), or otherwise deposited on or to the substrate prior to application or lamination of the dry film photoresist.

In some cases, the one or more image transfer processes or the one or more pattern transfer processes may include, without limitation, processes in which a photolithographic mask with a pattern is aligned over the photoresist-coated substrate and a light within a range of wavelengths associated with the photoresist material is used to interact with the molecules in the photoresist, thereby transferring the pattern of the photolithographic mask onto the photoresist. Depending on the type of photoresist, during a developing process, the light-exposed photoresist will either be removed or remain, while the remainder remains or is removed, correspondingly, thereby forming a mask on the substrate. Materials subsequently deposited on the remaining photoresist may be removed by dissolving the remaining photoresist on which the materials are subsequently deposited. These processes may be used to form the posts and/or other features.

In some instances, the one or more material plating processes may include, but are not limited to, electroplating of one or more metals (e.g., copper, nickel, tungsten, palladium, gold, silver, etc., and/or their alloys) onto at least portions of the substrate or at least portions of components formed thereon, or the like. In some cases, the one or more photoresist film stripping processes may include, without limitation, using solvent processing to lift-off or strip photoresist material that remains on the substrate, thereby also removing any materials that are deposited on the photoresist film, and leaving the deposited materials (that were not deposited on the photoresist film) to remain on the substrate (or layers thereon). In some instances, the one or more reflow processes may include, but are not limited to, forming a material onto at least portions of the substrate or at least portions of components formed thereon, and subsequently heating either the entire substrate or an area where the material is formed thereby causing the material to melt and flow. Once the material has been cooled, a new shape of the material on the at least portions of the substrate or the at least portions of components results (for example, solder reflow is described below, e.g., with respect to FIGS. 2E and 2F).

Herein, in some cases, the semiconductor device or package 105a or 105b may include a monolithic semiconductor package (which comprises a single chip structure; not shown) or a semiconductor package with a multi-chip structure(s) (such as shown in, but not limited to, FIG. 3O, or the like). In some embodiments, the semiconductor device or package 105a or 105b includes, but is not limited to, one of an application-specific integrated circuit (“ASIC”) semiconductor package, a system-on-a-chip (“SOC”) semiconductor package, a field programmable gate array (“FPGA”) semiconductor package, or other semiconductor package, or the like. Although FIGS. 1A and 1B (and similarly FIGS. 2A-2P and 3A-3N) depict semiconductor components formed on one side of the package substrate (in this case, the bottom side), the various embodiments are not so limited, and the semiconductor components may be formed on the other side (that is, the top side) or on both sides (that is, the top side and the bottom side, such as depicted in, e.g., FIG. 3O, or the like). Herein, the bottom side may have one or more layers, and these are referred to herein as “bottom layers” (similar, although not the focus herein, the top side may have one or more layers, and these would be referred to as “top layers”).

In some instances, the package substrate 110 includes a single layer substrate or a multi-layer substrate. In the case of a multi-layer substrate, the layers of the package substrate may include, but are not limited to, at least one of one or more dielectric layers, one or more power layers, one or more signal layers, or one or more other layers, and/or the like, and in some cases, may also be referred to as “one or more sublayers,” “one or more sub-layers,” “a buildup layer,” or “a build-up layer,” or the like.

Herein, a “power layer” may refer to one of (i) a layer (e.g., a “composite power layer” or the like) with one or more conductive traces communicatively coupled to a power source or power supply, the one or more conductive traces being of any suitable shape or size (length, width, thickness, etc.) and being separated from other conductive traces by dielectric or non-conductive material or the like; or (ii) a layer (e.g., a “power plane” or the like) comprising a conductive material throughout with dielectric or non-conductive material in the form of non-conductive trace lines separating regions of adjacent conductive regions that are communicatively coupled to different power supply sources (e.g., for supplying components with different voltage and/or current needs, etc.) and/or separating regions around vias connecting components/conductive traces on other layers but not said (power) layer; and/or the like.

Similarly, a “signal layer” may refer to one of (1) a layer (e.g., a “composite signal layer” or the like) with one or more conductive traces communicatively coupled to a signal sources or relays, the one or more conductive traces being of any suitable shape or size (length, width, thickness, etc.) and being separated from other conductive traces by dielectric or non-conductive material or the like; or (2) a layer (e.g., a “signal plane” or the like) comprising a conductive material throughout with dielectric or non-conductive material in the form of non-conductive trace lines separating regions of adjacent conductive regions that are communicatively coupled to different signal sources or relays and/or separating regions around vias connecting components/conductive traces on other layers but not said (signal) layer; and/or the like.

Likewise, a “ground layer” may refer to one of (a) a layer (e.g., a “composite ground layer” or the like) with one or more conductive traces communicatively coupled to a circuit ground, the one or more conductive traces being of any suitable shape or size (length, width, thickness, etc.) and being separated from other conductive traces by dielectric or non-conductive material or the like; or (b) a layer (e.g., a “ground plane” or the like) comprising a conductive material throughout with dielectric or non-conductive material in the form of non-conductive trace lines separating regions around vias connecting components/conductive traces on other layers but not said (ground) layer; and/or the like.

In some embodiments, the conductive trace lines (or non-conductive trace lines) need not be straight lines. For instance, the conductive trace lines or non-conductive trace lines may each include, without limitation, one or more traces that are each at least one of a straight line, a curved line, a patterned line, a labyrinthine line, a meandering line, a thick line, a thin line, or a combination thereof. In some cases, the conductive trace lines (or non-conductive trace lines) on a layer need not be vertically aligned with similar lines on other layers.

In some embodiments, the plurality of contact pads 115 may be communicatively coupled with vias and/or conductive trace lines in the package substrate 110 (not shown). Herein throughout, the term “coupled,” “couple,” or “coupling,” etc., respectively means “directly or indirectly coupled,” “directly or indirectly couple,” or “directly or indirectly coupling,” etc., or the like. The plurality of contact pads 115 are disposed between substrate 110 and solder mask layer 120. In some cases, the plurality of contact pads 115 may be in direct contact with an outermost layer of substrate 110 and with the solder mask layer 120. Alternatively, the plurality of contact pads 115 may be in direct contact with any suitable or appropriate number of intervening layers (including, but not limited to, one or more dielectric layers, one or more power layers, one or more signal layers, or one or more other layers, and/or the like) and in any suitable order between the contact pads 115 and one or both of a layer of the package substrate 110 and/or the solder mask layer 120. Also, as shown, e.g., in FIGS. 2I-2L, one or more contact pads among the plurality of contact pads 115 may be disposed at different layers 250 (or between different layers 250) of the package substrate 110 or other layers compared with other contact pads among the plurality of contact pads 115.

According to some embodiments, each post among the plurality of posts 125a or 125b includes, without limitation, a proximal end, a pillar portion, and a distal end. In some cases, each post is coupled at the proximal end to a conductive point on a layer among one or more layers of the package substrate 110 via a corresponding contact pad 115, each pillar portion having a length L or L′ extending along its axis between the proximal end and the distal end and a width d or d′ that is orthogonal to the length L or L′. In some cases, each post either may extend orthogonally from the contact pad to which it is attached (such as shown in FIGS. 1A-1B, 2B-2H, 2K, 2L, 2N-2P, 3B, 3D, 3F, 3H, 3J, and 3L-3O, or the like) or may be curved as it extends from the contact pad to which it is attached (not shown). In some instances, each post has a cross-sectional shape including, but not limited to, one of a circle, an ellipse, a triangle, a square, a rectangle, or other polygon, or the like. In some cases, the width d or d′ of a pillar portion of each of at least one first post among the plurality of posts 125a or 125b may be the same (or substantially the same; i.e., within a threshold of change in size ranging between 1 and 10%, inclusively, or between 1 and 25%, inclusively, or the like) throughout the length of the pillar portion of each of the at least one first post. In some other cases, the width d of a pillar portion of each of at least one first post among the plurality of posts 125a may be substantially different (i.e., not substantially the same as described above) throughout different sections along the length of the pillar portion of each of the at least one first post. For example, the width din the exposed section of the post 125a between the solder mask layer 120 and the solder anchor portions 130a can be larger or smaller than the width of the post in the section embedded in the solder mask layer 120 such as shown, e.g., in FIG. 1A. Alternatively, or additionally, the width d or d′ of a pillar portion of each of at least one second post among the plurality of posts 125a or 125b may be variable, yet continuously increasing and/or decreasing, throughout the length of the pillar portion of each of the at least one second post.

In some embodiments, the length L or L′ of the pillar portion of each of (three or more of) the plurality of posts is different from that of one or more adjacent posts. In some cases, the length of the pillar portion of each post is based on heights of corresponding contact points on the PCB and is not solely based on warpage of the package substrate. In some cases, the heights of the corresponding contact points on the PCB are determined based on a scan of a surface of the PCB. Herein, “not solely based” refers to the characteristic of the various embodiments that, although warpage of the package substrate (such as shown, e.g., in FIG. 3O, or the like, which shows the state of the package substrate after it has warped into a curved shape rather than a flat substrate) may contribute to the distances between contact pads on the package substrate and corresponding contact points on the PCB being different from those of adjacent contact pads and corresponding PCB contact points, the lengths of the posts are further configured to vary from those of adjacent posts due to such differences that are attributable to PCB contact point sizes (e.g., heights of contact points, and in some cases, lateral dimensions as well, or the like) and configurations themselves, in some cases, determinable by scanning of the surface of the PCB.

In some instances, in the case that the package substrate 110 comprises a plurality of substrate layers, one or more posts among the plurality of posts 125a or 125b are formed through two or more substrate layers among the plurality of substrate layers, where a cross-section of each of the one or more posts is continuous as it extends through the two or more substrate layers, without geometrical transitions in the cross-section of each post (such as shown in FIG. 2H) that exceeds a proportion of a width of the cross-section (e.g., 5, 10, 15, 20, or 25% of the width of the cross-section, or the like) as it extends between adjacent substrate layers among the two or more substrate layers. In some cases, the cross-section of each of the one or more posts is one of the same within a threshold amount of deviation (e.g., within 1, 5, 10, 15, 20, 25, or 50% deviation, or the like, preferably within 10% deviation), continuously expanding, or continuously contracting as it extends from the contact pad to which is it attached (in some cases, through the two or more substrate layers, or the like). According to some embodiments, at least one cross bar may be disposed to electrically connect two or more posts either between or among corresponding two or more pillars of said two or more posts or between or among corresponding contact pads to which said two or more posts are attached (e.g., cross bar 180 connecting contact pads 115 to which the third through sixth posts 125b of FIG. 1B are attached, or cross bars 280 of FIGS. 2N-2P, or cross bars 380 of FIG. 3B, 3D, 3E, 3F, 3H, 3J, or 3L, or the like). In some cases, the at least one cross bar may include conductive traces or other conductive materials, or the like.

In some embodiments, each solder anchor portion among the plurality of solder anchor portions 130a or 130b is coupled to the distal end of a corresponding post 125a or 125b, respectively. In some instances, each solder anchor portion has a width D or D′ that is larger than the width d or d′ (or average width in the case of variable width) of the pillar portion to which it is coupled. In some cases, each solder anchor portion has a shape including, but not limited to, one of a sphere, an ellipsoid (also referred to as an “oblong sphere,” an “oblate spheroid,” or a “spheroid,” or the like), a hemisphere, a cylinder, a cone, a truncated cone, a triangular prism, a cube, a rectangular prism, a pentagonal prism, a hexagonal prism, an octagonal prism, or other three-dimensional polygon, and/or the like. It should be understood that these shapes either can be regular (in which the corresponding sides, edges, diameters, or radii are equal; e.g., in the case of the sphere, a regular hemisphere, a regular triangular prism, a cube, a regular pentagonal prism, a regular hexagonal prism, a regular octagonal prism, or other regular three-dimensional polygon, or the like) or can be irregular (in which in which the corresponding sides, edges, diameters, or radii are not equal; e.g., in the case of the ellipsoid, an oblate hemisphere, the cylinder, the cone, the truncated cone, an irregular triangular prism, the rectangular prism, an irregular pentagonal prism, an irregular hexagonal prism, an irregular octagonal prism, or other irregular three-dimensional polygon, or the like).

In some instances, each solder ball among the plurality of solder balls 135a or 135b is disposed on and around the solder anchor portion 130a or 130b, respectively, of a corresponding post 125a or 125b. In some cases, one or more solder balls among the plurality of solder balls 135a or 135b and corresponding one or more posts among the plurality of posts 125a or 125b forming conductive interconnects between corresponding conductive points or contact pads 115 on the package substrate 110 and corresponding contact points on a PCB (e.g., PCB board 390 of FIG. 3O, or the like). In some embodiments, a “solder ball” may refer to an amount of solder that takes the form of a ball or elongated ball, and serves as a conductive point of connection between two components (one on or extending from the package substrate, in this case, the post or solder anchor portion; the other on or extending from the PCB, or the like). In some instances, the plurality of solder balls may be similar to components of ball grid arrays (“BGAs”) or the like, except that the solder balls are disposed at the end of posts (in particular, the solder anchor portions of such posts), according to the various embodiments. According to some embodiments, a “solder anchor portion” may refer to a structure disposed at the distal end of a post that is configured to facilitate anchoring of a solder ball at the end of the post while minimizing occurrence of the solder ball falling off the distal end of the post. In some cases, a solder anchor portion may be configured based on a combination of gravitational force, surface tension of the solder material (of the solder ball), and/or shape and configuration of the solder anchor to define a shape of each solder ball, and/or the like. In some embodiments, a solder anchor portion having a width that is larger than a width of a distal end of a pillar portion of a post to which it is coupled (e.g., as shown, e.g., in FIGS. 1A, 1B, 2F, 2H, 2L, 2P, 3D, 3H, and 3O, or the like) may facilitate anchoring of a solder ball at the end of the post while minimizing occurrence of the solder ball falling off the distal end of the post. Alternatively, or additionally, a solder anchor portion having edges and/or vertices (e.g., solder anchor portions having a shape including, but not limited to, one of a cylinder, a cone, a truncated cone, a triangular prism, a cube, a rectangular prism, a pentagonal prism, a hexagonal prism, an octagonal prism, or other three-dimensional polygon, and/or the like) may also facilitate anchoring of a solder ball at the end of the post while minimizing occurrence of the solder ball falling off the distal end of the post. In some cases, the shape, configuration, and/or size of the solder anchor portion may be designed or selected to take into account the surface tension of the solder material (of the solder ball) in counter-action to gravitational force on the solder ball as it hangs from the solder anchor portion. Herein, the solder ball being disposed “on” the solder anchor portion may include the solder ball either being disposed directly on the solder anchor portion or being disposed on the solder anchor portion indirectly with one or more intervening materials between the solder and the solder anchor portion (e.g., coating(s) on the solder anchor portion to further facilitate anchoring of the solder ball to the solder anchor portion, and/or the like), or the like. Herein also, the solder ball being disposed “on and around” the solder anchor portion may include the solder ball either being disposed (directly or indirectly) on and around an entirety of the exposed surfaces of the solder anchor portion (as shown, e.g., in FIGS. 1A, 1B, 2F, 3D, 3H, and 3O, or the like) or being disposed (directly or indirectly) on and around at least portions of the exposed surfaces of the solder anchor portion (not shown), or the like.

In some embodiments, the package substrate 110 includes one or more layers, each comprising conductive materials, including, but not limited to, copper, aluminum, silver, or other material, and/or the like, and dielectric materials, including, but not limited to, flame retardant (“FR”) grade designation for glass-reinforced epoxy laminate material (“FR-4” or “FR4”), bismaleimide triazine (“BT”) resin or epoxy material, Ajinomoto Build-up Film (“ABF”), or other suitable material, and/or the like. In some cases, the solder material may include, without limitation, lead free material (e.g., tin, silver, copper, bismuth, indium, zinc, or antimony-based solder, or the like), tin-silver or tin-silver-based alloy, or tin-silver-copper or tin-silver-copper-based alloy, and/or the like. In some instances, the posts 125 each comprises materials including, but not limited to, copper, gold, silver, platinum, or any electrically conductive material or alloy, and/or the like. In some cases, the contact pads 115 may comprise materials including, but not limited to, copper, or other material, or the like.

The various embodiments of the novel semiconductor package interconnection structure(s) between the package substrate and the PCB on which the package substrate is mounted allow for an increased stand-off height H or H′, defined by a distance between a proximal end of the post and a distal end of a solder ball that is disposed on a solder anchor portion attached to the distal end of the post. With such a structure, smaller solder balls (i.e., with smaller widths W or W) may be achieved to enable an increased stand-off height H, thereby allowing for greater density of components due to decreased pitch p or p′, which is defined by a distance between a center of one I/O or post and that of an adjacent or neighboring I/O or post. With stand-off height H or H′ increasing to a height ranging between 0.25 and 2.50 mm, inclusively, thereby reducing board level stresses for semiconductor packages larger than 45×45 mm, or the like, solder ball sizes can be reduced to widths W or W′ ranging between 0.2 and 0.4 mm, inclusively, allowing for increased input/output (“I/O”) density using smaller pitches of p or p′ ranging between 0.30 and 0.65 mm, inclusively.

These and other functions of the system 100 (and its components) are described in greater detail below with respect to FIGS. 2-4.

FIGS. 2A-2P (collectively, “FIG. 2”) are schematic diagrams illustrating various non-limiting examples of semiconductor package manufacturing processes for forming various examples 200, 200′, 200″, and 200′″ of a semiconductor device with a novel semiconductor package interconnection structure(s) between a package substrate and a PCB on which the package substrate is to be mounted, in accordance with various embodiments.

As shown in the non-limiting example 200 of FIGS. 2A-2F, a semiconductor device 205 with a novel semiconductor package interconnection structure(s) is formed as follows. After forming a package substrate including, without limitation, a first layer or substrate layer 210, a second layer or solder mask layer 220, and a plurality of contact or conductive pads 215 that is formed between the first layer or substrate layer 210 and the second layer or solder mask layer 220, a plurality of first openings 220a are formed in the second layer or solder mask layer 220 to expose portions of the contact pads 215 (as shown, e.g., in FIG. 2A). After a third layer or sacrificial layer (also referred to as a “dry film” layer, or the like) 240a is formed on or over the second layer or solder mask layer 220 and another plurality of first openings is formed therethrough (in some cases, with the third layer being formed prior to the first openings being formed in both the second and third layers to expose the contact pads 215), a pillar portion of each post 225 is formed within one of the plurality of first openings (as shown, e.g., in FIG. 2B). After a fourth layer or sacrificial layer 240b is formed on or over the third layer 240a and the pillar portions of the plurality of posts 225, a plurality of second openings is formed in the fourth layer 240b, and a plurality of solder anchor portions 230 is formed for corresponding plurality of posts 225 within the corresponding plurality of second openings (as shown, e.g., in FIG. 2C). After a fifth layer or sacrificial layer 240c is formed on or over the fourth layer 240b and the solder anchor portion 230 for each post, a plurality of third openings is formed in the fifth layer 240c and in the fourth layer 240b, a solder shell 245 is formed for each post 225 within one of the plurality of third openings, such that each solder shell 245 covers a distal portion and side portions of the corresponding solder anchor portion 230 for each post 225 (as shown, e.g., in FIG. 2D). The third, fourth, and fifth layers 240a-240c are then removed (as shown, e.g., in FIG. 2E), and solder reflow (in some cases, with the semiconductor device 205 or the solder shells 245 being heated until the solder material melts or becomes molten) is performed, resulting in formation of solder balls 235 (as shown, e.g., in FIG. 2F), which, in some cases, may be based on a combination of gravitational force, surface tension of the solder material, and shape and configuration of the solder anchor to define a shape of each solder ball, and/or the like. As shown in FIGS. 2A-2F, the width of the pillar portion may be defined by a width of each first opening, each of the plurality of second openings has a width that is greater than the width of the distal end of the pillar portion and is centered on the pillar portion of a corresponding post, and each of the plurality of third openings has a width that is greater than the width of the solder anchor portion and is centered on the solder anchor portion. In some cases, centering need not be precise and centering may refer to placement within a tolerance of half the width of the component being centered around (e.g., the second openings may be centered on a pillar portion of the corresponding post to within a tolerance of half the width of the pillar portion, or the third openings may be centered on the solder anchor portion to within a tolerance of half the width of the solder anchor portion, etc.).

As shown in the non-limiting example 200′ of FIGS. 2G and 2H, the various embodiments implement direct drop-down posts 225 or 270 rather than typical non-direct drop-down posts 255. The former is characterized by a cross-section that is uniform or that changes uniformly (or extends continuously) throughout its length, without geometrical transitions in the cross-section of each post (e.g., geometrical transitions 260 as shown in FIG. 2G, or the like) that exceeds a proportion of a width of the cross-section as it extends between adjacent substrate layers among the two or more substrate layers (such as layers 250a-250c as shown in FIG. 2G, or the like), which is characteristic of the latter. In particular, FIG. 2G depicts a comparison between a direct drop-down post 225 (as shown on the left side of the dashed lines in FIG. 2G) and a non-direct drop-down post 255, with segments 255a-255c for each layer 250a-250c, respectively, and with geometrical transitions 260 between pairs of segments 255a/255b and 255b/255c between corresponding pairs of layers 250a/250b and 250b/250c, respectively. Herein, “geometrical transitions” may be defined by the width (or diameter) of a segment 255a (or 255b) being different from the width (or diameter) of an adjacent segment 255b (or 255c) at the transition between the layers of the package substrate 250a (or 250b) and 250b (or 250c) in which the segments 255a (or 255b) and 255b (or 255c) are disposed, such as shown, e.g., in FIGS. 2G, and/or may be defined by the amount of deviation in size or proportion compared with a width of the cross-section (e.g., 5, 10, 15, 20, 25, or 50%, or greater, of the width of the cross-section, or the like).

FIG. 2H depicts a comparison of different levels or depths of drop-down for posts 225 and 270: (1) the left side of FIG. 2H depicts a direct drop-down post 270b extending, through solder mask layer 220, from direct contact (in this case, distal-to-proximal contact) between post 270b and through-hole via 265c extending through layer 250b, the through-hole via 265c being in direct contact (in this case, side-to-side contact, although may be distal-to-proximal contact as shown in FIG. 1 or 2B-2F, or the like) with contact pad 215b that is disposed in, on, or through layer 250a or 250b, the contact pad 215b being communicatively coupled with through-hole via 265b in layer 250a, with through-hole via 265b in turn being in direct contact (in this case, side-to-side contact, although may be distal-to-proximal contact as shown in FIG. 1 or 2B-2F, or the like) with contact pad 215a that is disposed in, on, or through layer 250a (the contact pad 215a being communicatively coupled with through-hole via 265a); (2) the middle portion of FIG. 2H depicts a direct drop-down post 270a extending, through layers 250b and solder mask layer 220, replacing the through-hole via 265c and post 270b in the left portion of FIG. 2H; and (3) the right side of FIG. 2H depicts a direct drop-down post 225 extending, through layers 250a, 250b, and solder mask layer 220, from direct contact (in this case, side-to-side contact, although may be distal-to-proximal contact as shown in FIG. 1 or 2B-2F, or the like) with contact pad 215a, replacing the through-hole via 265b and contact pad 215b of the middle portion of FIG. 2H. As local stress concentration moves closer to the core layer 210, reliability risk due to via undercut (e.g., due to geometrical transitions, or the like) may be minimized or eliminated. Due to the number of geometrical transitions being reduced in number or eliminated, impedance mismatch between the post segments or portions between layers can be minimized, which results in improved signal integrity due to current flow cross-section not changing for direct drop-down post 225 compared with changing current flow cross-section for non-direct drop-down post 255.

The non-limiting example 200″ of FIGS. 2I-2L depicts embodiments in which contact pads 215 are disposed in, on, or through different layers of the package substrate (in this case, layers 210 and 250a-250c), with openings 275 being formed through the intervening layers to the contact pads 215 (as shown, e.g., in FIG. 2J), with pillars of posts 225 being formed in the openings 275 (as shown, e.g., in FIG. 2K), and with solder mask layer 220, the remainder of the posts 225, the solder anchor portions 230, and the solder shells 245 being formed thereafter (as shown, e.g., in FIG. 2L; in accordance with the process as shown and described above with respect to FIGS. 2A-2E). In some embodiments, processes including, but not limited to, laser drill or plasma dry etching such as reported in Morikawa et al, “Fabrication of Ultra-Fine Vias in Low CTE Build-up Films Using a Novel Dry Etching Technology,” 2015 IEEE 65th Electronic Components and Technology Conference (ECTC), pp. 1494-1497, May, 2015 (which is incorporated herein by reference in its entirety for all purposes) may be used to form the openings 275 and/or openings for forming the posts 225 (as described with respect to FIGS. 1 and 2).

The non-limiting example 200′″ of FIGS. 2M-2P depicts embodiments in which a cross bar 280 is formed to couple two or more posts 225, with cross bars being formed in layer 240a connecting adjacent posts 225 (as shown, e.g., in FIG. 2N), with posts being extended in layer 240b beyond posts 225 and cross bars 280 in layer 240a (as shown, e.g., in FIG. 2O), and with solder anchors 230 and solder shells 245 being formed thereafter (as shown, e.g., in FIG. 2P; in accordance with the process as shown and described above with respect to FIGS. 2C-2E).

These and other functions of the examples 200, 200′, 200″, and 200′″ (and their components) are described in greater detail herein with respect to FIGS. 1, 3, and 4.

FIGS. 3A-3O (collectively, “FIG. 3”) are schematic diagrams illustrating various non-limiting examples of wire-bonding-based processes for forming various examples 300, 300′, 300″, 300′″, 300″″, and 300″″ of a semiconductor device with a novel semiconductor package interconnection structure(s) between a package substrate and a PCB on which the package substrate is to be mounted, in accordance with various embodiments.

As shown in the non-limiting example 300 of FIGS. 3A-3D, a semiconductor device 305 with a novel semiconductor package interconnection structure(s) is formed as follows. After forming a package substrate including, without limitation, a first layer or substrate layer 310, a second layer or solder mask layer 320, and a plurality of contact or conductive pads 315 that is formed between the first layer or substrate layer 310 and the second layer or solder mask layer 320, a plurality of first openings 320a are formed in the second layer or solder mask layer 320 to expose portions of the contact pads 315 (as shown, e.g., in FIG. 3A). Thereafter, wire bonding or wire bonding-based processes are used to affix or attach (in some cases, using stitch metal or other bonding material, depicted in FIG. 3 by the pile of hemispherical-like structures between each post 325 and corresponding contact pad 315) each post 325 to an exposed portion of a corresponding one of the plurality of conductive pads 315, each post 325 is broken to a respective determined length of the pillar portion of the post, and a ball tip 330 is formed as the solder anchor portion at the distal end of each post (as shown, e.g., in FIG. 3B). The package substrate is then lowered such that the ball tip 330 for each post 325 is dipped into one of a partitioned portion of a tray of molten solder material 345 or a pool of molten solder material 345, during solder reflow (the molten solder material in ball form being shown in FIG. 3C; the tray and pool not being shown in FIG. 3), and is then raised or lifted, resulting in solder balls 335 clinging to the ball tips 330 (as shown, e.g., in FIG. 3D).

In some embodiments, the ball tip 330, which serves a similar role as solder anchor portion 130 and 230 of FIGS. 1 and 2, may be formed using ball tip formation techniques based on capillary force of the molten metal, or the like. In some cases, high-voltage electric discharge, or the like, is used to break the pillar at a determined position to achieve the determined length. In some instances, the length of the pillar portion of each post is determined based on the determined heights of corresponding contact points on the PCB, which may result in the length of the pillar portion of each of the plurality of posts being different from that of one or more adjacent posts (such as shown, e.g., in example 300′ of FIGS. 3E-3H, or the like). For example, as shown in FIG. 3H, stand-off height H′ (defined by the distance between the distal end of solder mask layer 320 and the distal end of solder ball 335) varies as follows (although not limited to such example): (i) H′ of the second post 325 is greater than that of the first, third, and seventh posts (as seen from the left in FIG. 3H); (ii) H′ of the third post 325 is less than that of the other posts 325; (iii) H′ of the fourth post 325 is greater than that of the other posts 325; (iv) H′ of the fifth post 325 is less than that of the fourth and sixth posts 325; (v) H′ of the sixth post 325 is greater than that of the first, second, third, fifth, and seventh posts; and (vi) H′ of the seventh post 325 is less than that of the second, fourth, fifth, and sixth posts. Alternatively, the length of the pillar portion of each of the plurality of posts is the same as that of all adjacent posts (such as shown, e.g., in example 300 of FIGS. 3A-3D, or the like).

Herein, a “tray” of molten solder material refers to a container (not unlike an egg carton or ice cube tray in general shape albeit comprising a material having temperature-resistant and liquid-holding characteristics capable of containing molten solder material, or the like) that has internal partitions holding mini-pools of the molten solder material into which one or a small number (i.e., less than half) of posts 325 with ball tips 330 are lowered. Herein also, a “pool” of molten solder material refers to a container without internal partitions into which all the posts 325 of the semiconductor device 305a (or 305b in the case of example 300′ of FIGS. 3E-3H) are lowered. In the case of example 300′, the “tray” is either configured to have different depths or configured to be deeper than an expected longest distance between shortest post and longest post, while the “pool” is configured to be deeper than the expected longest distance between shortest post and longest post.

The non-limiting example 300″ of FIGS. 31 and 3J depicts embodiments in which contact pads 315 are disposed in, on, or through a layer of the package substrate 305c, with posts 325 (affixed to the contact pads 315) extending through openings 350a in substrate layer 350 (as shown, e.g., in FIG. 3J). In an alternative, non-limiting example 300′″ of FIGS. 3K and 3L depicts embodiments in which contact pads 315 are disposed in, on, or through an outermost layer of the package substrate 305d, with posts 325 (affixed to the contact pads 315) extending from the contact pads 315 and (similar height) solder mask layer 320) that are formed on substrate layer 350 (as shown, e.g., in FIG. 3L). The non-limiting example 300″″ of FIGS. 3M and 3N depicts package substrate 305c of FIG. 3J (although package substrate 305d of FIG. 3L may alternatively be used) being attached to an interposer substrate 385 having through-holes through which posts 325 of semiconductor device 305c (or 305d) may be passed, resulting in the combined structure as shown in, e.g., FIG. 3N, or the like. In FIGS. 3I-3N, the ball tips 330 and solder balls 335 are not shown for simplicity of illustration, but would otherwise be similar, if not identical, to those shown in FIGS. 1B, 3B, 3D, 3F, and/or 3H, or the like. In some cases, the interposer substrate 385 may comprise materials including, but not limited to, silicon, glass, BT, FR4, tape, and/or the like.

As shown in the non-limiting example 300′″″ of FIG. 3O, a multi-chip semiconductor device 305e, on which chips 1-3 are attached to a package substrate, which in turn is attached or attachable to a PCB 390. As shown in FIG. 3O, due to various reasons including, but not limited to, increased density of components on chips and increased density of chips on package substrates, warpage (or state after warping) of the package substrate(s) may occur, which may be described in terms of a warpage profile or the like. Although concave warpage profile is shown in FIG. 3O, other warpage profiles, including, without limitation, convex warpage profile, a “W” shaped profile, an “M” shaped profile, or the like, may be possible. Adjusting the heights or lengths of posts extending from a bottom of a package substrate to conform to the shape of the multi-chip device is advantageous. Beyond this, however, the various embodiments also take into account differing or varying heights of corresponding contact points on the PCB (and not solely based on warpage of the package substrate), where the heights of the corresponding contact points on the PCB may be determined based on a scan of a surface of the PCB. The result is as shown in the zoomed-in view depicted within the rectangular cut-out in FIG. 3O, in which the lengths of the posts of semiconductor device 305e (as formed according to the processes as described above with respect to FIGS. 3A-3H, or the like) are configured to conform to the varying heights of components of PCB 390, as determined by a scan of the surface of the PCB 390. Subsequently, solder reflow may be performed as the semiconductor device 305e is brought closer to PCB 390, resulting in the solder balls on the posts merging with corresponding contact points 390a (or solder balls on corresponding contact points 390a (not shown)) on the PCB, thereby bonding the semiconductor device 305e to the PCB 390 (and allowing electrical connection between portions of chips 1-3 and corresponding components on, mounted on, or connected to PCB device 390, or the like). Herein, “contact points” on the PCB may be similar in structure as contact pads on the package substrate, although, in some instances, some contact points on the PCB may have different heights compared to adjacent contact points.

These and other functions of the examples 300, 300′, 300″, 300′″, 300″″, and 300′″″ (and their components) are described in greater detail herein with respect to FIGS. 1, 2, and 4.

Although FIGS. 1-3 depict cross-sections (or two-dimensional) views of the various embodiments, similar features extend also into three-dimensions. For example, although the varying lengths of posts as shown, e.g., in FIG. 3H or 3O, or the like, are shown in two dimensions, such varying lengths of posts may extend in three dimensions also (although not shown). Also although particular components and layers and order of components and layers are shown and described above with respect to FIGS. 1-3, the various embodiments are not so limited, and the various components and layers may be in any suitable order with any suitable number and type of intervening components and layers (including sub-layers, multi-layers, and/or the like).

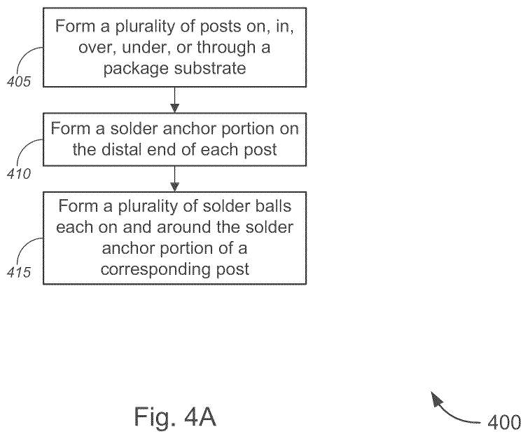

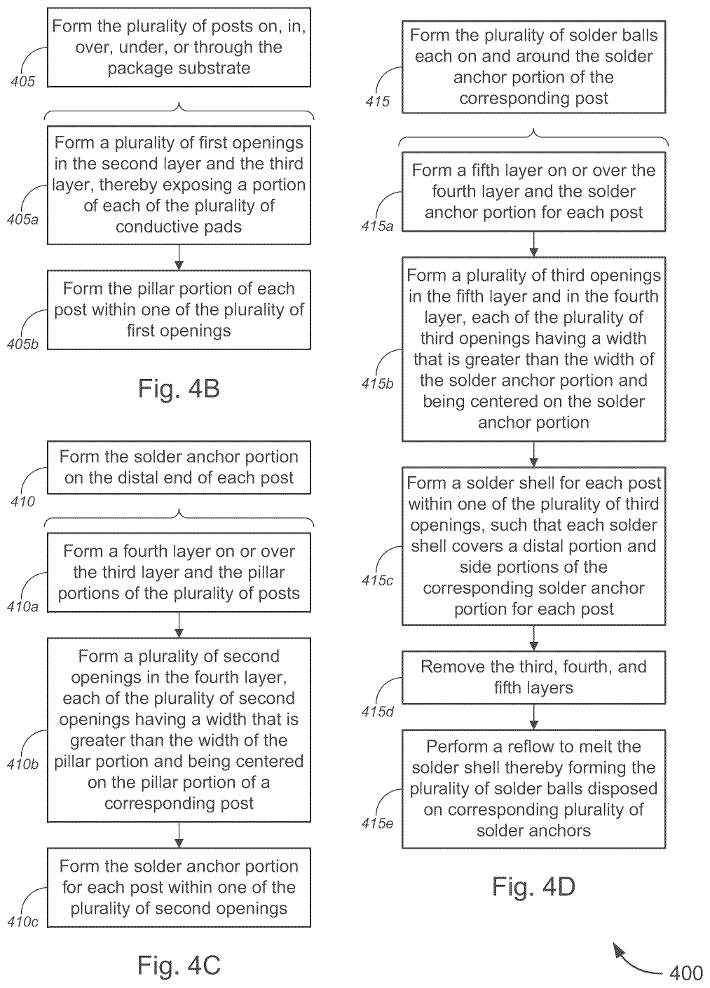

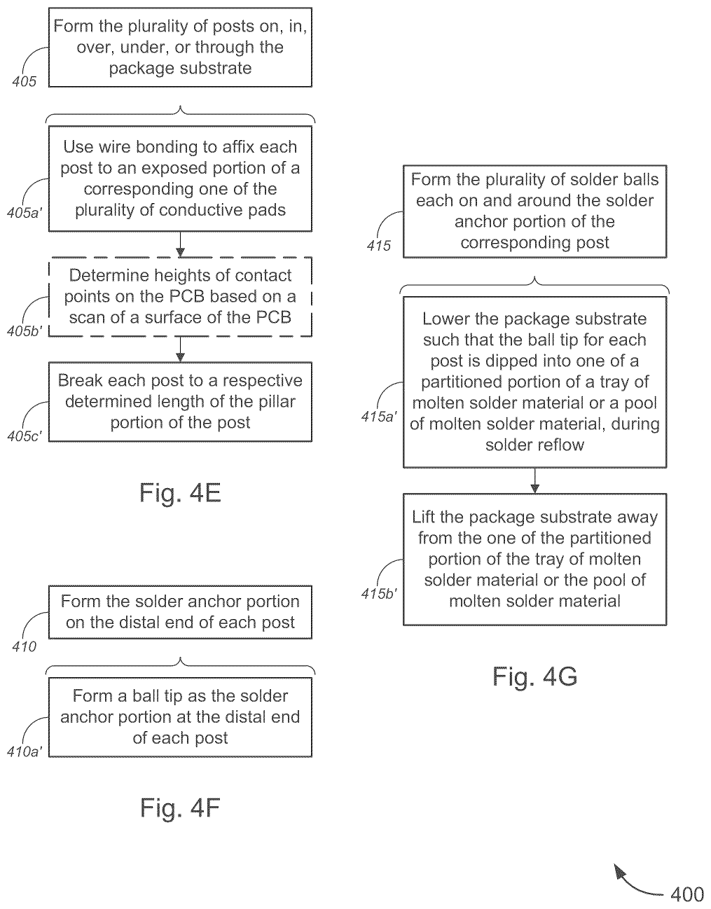

FIGS. 4A-4G (collectively, “FIG. 4”) are flow diagrams illustrating a method 400 for forming a semiconductor device with a novel semiconductor package interconnection structure(s) between a package substrate and a PCB on which the package substrate is to be mounted, in accordance with various embodiments.

While the techniques and procedures are depicted and/or described in a certain order for purposes of illustration, it should be appreciated that certain procedures may be reordered and/or omitted within the scope of various embodiments. Moreover, while the method 400 illustrated by FIG. 4 can be implemented by or with (and, in some cases, are described below with respect to) the systems, examples, or embodiments 100, 100′, 200, 200′, 200″, 200′″, 300, 300′, 300″, 300′″, 300″″, and 300′″″ of FIGS. 1A, 1B, 2A-2F, 2G-2H, 2I-2L, 2M-2P, 3A-3D, 3E-3H, 3I-3J, 3K-3L, 3M-3N, and 3O, respectively (or components thereof), such methods may also be implemented using any suitable hardware (or software) implementation for semiconductor package manufacturing processes. Similarly, while each of the systems, examples, or embodiments 100, 100′, 200, 200′, 200″, 200′″, 300, 300′, 300″, 300′″, 300″″, and 300″″ of FIGS. 1A, 1B, 2A-2F, 2G-2H, 2I-2L, 2M-2P, 3A-3D, 3E-3H, 3I-3J, 3K-3L, 3M-3N, and 3O, respectively (or components thereof), can operate according to the method 400 illustrated by FIG. 4, the systems, examples, or embodiments 100, 100′, 200, 200′, 200″, 200′″, 300, 300′, 300″, 300′″, 300″″, and 300′″″ of FIGS. 1A, 1B, 2A-2F, 2G-2H, 2I-2L, 2M-2P, 3A-3D, 3E-3H, 3I-3J, 3K-3L, 3M-3N, and 3O can each also operate according to other modes of operation and/or perform other suitable procedures.

In the non-limiting embodiment of FIG. 4A, method 400, at block 405, comprises forming a plurality of posts on, in, over, under, or through a package substrate, the package substrate comprising one or more layers, each post including, without limitation, a proximal end, a pillar portion, and a distal end, each post being coupled at the proximal end to a conductive point on a layer among the one or more layers of the package substrate, each pillar portion having a length extending along its axis between the proximal end and the distal end and a width at the distal end that is orthogonal to the length.

At block 410, method 400 comprises forming a solder anchor portion on the distal end of each post. In some embodiments, each solder anchor portion has a width that is larger than the width of the distal end of the pillar portion to which it is coupled.

Method 400 further comprises, at block 415, forming a plurality of solder balls each on and around the solder anchor portion of a corresponding post. In some cases, one or more solder balls among the plurality of solder balls and corresponding one or more posts among the plurality of posts forms conductive interconnects between corresponding conductive points on the package substrate and corresponding contact points on a PCB.

FIGS. 4B-4D are directed to the processes of steps 405-415 being performed using semiconductor package manufacturing processes, such as shown and described above with respect to FIG. 2, or the like. In some instances, such semiconductor package manufacturing processes may include, but are not limited to, at least one of one or more photoresist film application processes, one or more image transfer processes, one or more pattern transfer processes, one or more material plating processes, one or more photoresist film stripping processes, or one or more reflow processes, and/or the like. FIGS. 4E-4G are directed to processes of steps 405-415 being performed using wire bonding-based processes, such as shown and described above with respect to FIG. 3, or the like.

With reference to FIGS. 4B-4D, the package substrate comprises a first layer, a second layer, a plurality of conductive pads that is formed between the first layer and the second layer, and a third layer that is formed on or over the second layer. In some instances, such as shown in FIG. 4B, forming the plurality of posts on, in, over, under, or through the package substrate (at block 405) comprises: forming a plurality of first openings in the second layer and the third layer, thereby exposing a portion of each of the plurality of conductive pads, wherein a width of each first opening defines the width of the pillar portion (block 405a); and forming the pillar portion of each post within one of the plurality of first openings (block 405b). Alternatively (although not shown in FIG. 4), forming the plurality of posts on, in, over, under, or through the package substrate (at block 405) comprises: forming a plurality of first openings in the second layer, thereby exposing a portion of each of the plurality of conductive pads, wherein a width of each first opening defines the width of a first section of the pillar portion; and forming the first section of the pillar portion of each post within one of the plurality of first openings; forming the third layer; forming a plurality of additional openings in the third layer, wherein a width of each additional opening defines the width of a second section of the pillar portion; and forming the second section of the pillar portion of each post within one of the plurality of first openings. In some instances, the width of the second section is one of substantially the same (as described above with respect to width d or d′ of a pillar portion of each of at least one first post among the plurality of posts 125a or 125b, and with respect to FIG. 1) as, greater than, or less than that of the first section. In some cases, such as shown in FIG. 4C, forming the solder anchor portion on the distal end of each post (at block 410) comprises: forming a fourth layer on or over the third layer and the pillar portions of the plurality of posts (block 410a); forming a plurality of second openings in the fourth layer, each of the plurality of second openings having a width that is greater than the width of the distal end of the pillar portion and being centered on the pillar portion of a corresponding post (block 410b); and forming the solder anchor portion for each post within one of the plurality of second openings (block 410c).

In some embodiments, such as shown in FIG. 4D, forming the plurality of solder balls each on and around the solder anchor portion of the corresponding post (at block 415) comprises: forming a fifth layer on or over the fourth layer and the solder anchor portion for each post (block 415a); forming a plurality of third openings in the fifth layer and in the fourth layer, each of the plurality of third openings having a width that is greater than the width of the solder anchor portion and being centered on the solder anchor portion (block 415b); forming a solder shell for each post within one of the plurality of third openings, such that each solder shell covers a distal portion and side portions of the corresponding solder anchor portion for each post (block 415c); removing the third, fourth, and fifth layers (block 415d); and performing a reflow to melt the solder shell thereby forming the plurality of solder balls disposed on corresponding plurality of solder anchors (block 415e).

Referring to FIGS. 4E-4G, the package substrate comprises a first layer, a second layer, and a plurality of conductive pads that is formed between the first layer and the second layer, wherein a plurality of openings is formed in the second layer thereby exposing a portion of each of the plurality of conductive pads. In some instances, such as shown in FIG. 4E, forming the plurality of posts on, in, over, under, or through the package substrate (at block 405) comprises: using wire bonding to affix each post to an exposed portion of a corresponding one of the plurality of conductive pads (block 405a′); determining heights of contact points on the PCB based on a scan of a surface of the PCB (optional block 405b′); and breaking each post to a respective determined length of the pillar portion of the post (block 405c′), in some cases, using high-voltage electric discharge, or the like, to break the pillar at a determined position to achieve the determined length. In some instances, the length of the pillar portion of each post is determined based on the determined heights of corresponding contact points on the PCB. In some embodiments, the length of the pillar portion of each of the plurality of posts is different from that of one or more adjacent posts. Alternatively, the length of the pillar portion of each of the plurality of posts is the same as that of all adjacent posts.

In some cases, such as shown in FIG. 4F, forming the solder anchor portion on the distal end of each post (at block 410) comprises: forming a ball tip as the solder anchor portion at the distal end of each post (block 410a′), in some cases, using ball tip formation techniques based on capillary force of the molten metal, or the like.

According to some embodiments, such as shown in FIG. 4G, forming the plurality of solder balls each on and around the solder anchor portion of the corresponding post (at block 415) comprises: lowering the package substrate such that the ball tip for each post is dipped into one of a partitioned portion of a tray of molten solder material or a pool of molten solder material, during solder reflow (block 415a′); and lifting the package substrate away from the one of the partitioned portion of the tray of molten solder material or the pool of molten solder material (block 415b′).

While particular features and aspects have been described with respect to some embodiments, one skilled in the art will recognize that numerous modifications are possible. For example, the methods and processes described herein may be implemented using hardware components, software components, and/or any combination thereof. Further, while various methods and processes described herein may be described with respect to particular structural and/or functional components for ease of description, methods provided by various embodiments are not limited to any particular structural and/or functional architecture but instead can be implemented on any suitable hardware, firmware and/or software configuration. Similarly, while particular functionality is ascribed to particular system components, unless the context dictates otherwise, this functionality need not be limited to such and can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with—or without—particular features for ease of description and to illustrate some aspects of those embodiments, the various components and/or features described herein with respect to a particular embodiment can be substituted, added and/or subtracted from among other described embodiments, unless the context dictates otherwise. Consequently, although several embodiments are described above, it will be appreciated that the invention is intended to cover all modifications and equivalents within the scope of the following claims.

What is claimed is:

1. A semiconductor device, comprising:
a package substrate comprising one or more layers;
a plurality of posts, each post comprising a proximal end, a pillar portion, a distal end, and a solder anchor portion, each post being coupled at the proximal end to a conductive point on a layer among the one or more layers of the package substrate, each pillar portion having a length extending along its axis between the proximal end and the distal end and a width at the distal end that is orthogonal to the length, each solder anchor portion being coupled to the distal end of a corresponding post, wherein each solder anchor portion has a width that is larger than the width of the distal end of the pillar portion to which it is coupled; and
a plurality of solder balls, each solder ball being disposed on and around the solder anchor portion of a corresponding post, one or more solder balls among the plurality of solder balls and corresponding one or more posts among the plurality of posts forming conductive interconnects between corresponding conductive points on the package substrate and corresponding contact points on a printed circuit board (“PCB”) device.

2. The semiconductor device of claim 1, wherein the conductive points on the package substrate comprise a plurality of conductive pads, each conductive pad being coupled to the proximal end of a corresponding post among the plurality of posts.

3. The semiconductor device of claim 2, wherein the plurality of posts is formed on the plurality of conductive pads using semiconductor package manufacturing processes comprising at least one of one or more photoresist film application processes, one or more image transfer processes, one or more pattern transfer processes, one or more material plating processes, one or more photoresist film stripping processes, or one or more reflow processes.

4. The semiconductor device of claim 3, wherein the plurality of posts is formed on the package substrate extending from a bottom layer of the package substrate, such that the plurality of solder balls is formed by forming a solder shell around the solder anchor portion of each post.

5. The semiconductor device of claim 2, wherein the plurality of posts is formed on the plurality of conductive pads using wire bonding processes.

6. The semiconductor device of claim 5, wherein the plurality of posts is formed on the package substrate extending from a bottom layer of the package substrate, such that the plurality of solder balls is formed by applying molten solder material to the solder anchor portion of each post.

7. The semiconductor device of claim 1, wherein the solder anchor portion has a shape comprising one of a sphere, an ellipsoid, a hemisphere, a cylinder, a cone, a truncated cone, a triangular prism, a cube, a rectangular prism, a pentagonal prism, a hexagonal prism, an octagonal prism, or other three-dimensional polygon.

8. The semiconductor device of claim 1, wherein one or more posts among the plurality of posts are formed through two or more substrate layers among the one or more layers of the package substrate, wherein a cross-section of each of the one or more posts is continuous as it extends through the two or more substrate layers, without geometrical transitions in the cross-section of each post that exceeds a proportion of a width of the cross-section as each post extends between adjacent substrate layers among the two or more substrate layers.

9. The semiconductor device of claim 8, wherein the cross-section of each of the one or more posts is one of the same within a threshold amount of deviation of 10%, continuously expanding, or continuously contracting as it extends through the two or more substrate layers.

10. The semiconductor device of claim 1, wherein two or more posts among the plurality of posts are connected to each other via one or more cross bars.

11. The semiconductor device of claim 1, wherein the length of the pillar portion of each of the plurality of posts is different from that of one or more adjacent posts, wherein the length of the pillar portion of each post is based on heights of corresponding contact points on the PCB and is not solely based on warpage of the package substrate, wherein the heights of the corresponding contact points on the PCB are determined based on a scan of a surface of the PCB.

12. A method, comprising:
forming a plurality of posts on a package substrate, the package substrate comprising one or more layers, each post comprising a proximal end, a pillar portion, and a distal end, each post being coupled at the proximal end to a conductive point on a layer among the one or more layers of the package substrate, each pillar portion having a length extending along its axis between the proximal end and the distal end and a width at the distal end that is orthogonal to the length; and
forming a solder anchor portion on the distal end of each post, wherein each solder anchor portion has a width that is larger than the width of the distal end of the pillar portion to which it is coupled.

13. The method of claim 12, further comprising:
forming a plurality of solder balls each on and around the solder anchor portion of a corresponding post, one or more solder balls among the plurality of solder balls and corresponding one or more posts among the plurality of posts forming conductive interconnects between corresponding conductive points on the package substrate and corresponding contact points on a printed circuit board (“PCB”) device.

14. The method of claim 13, wherein the package substrate comprises a first layer, a second layer, a plurality of conductive pads that is formed between the first layer and the second layer, and a third layer that is formed on or over the second layer, wherein:
forming the plurality of posts on the package substrate comprises:
forming a plurality of first openings in the second layer and the third layer, thereby exposing a portion of each of the plurality of conductive pads, wherein a width of each opening defines the width of the pillar portion; and
forming the pillar portion of each post within one of the plurality of first openings; and
forming the solder anchor portion on the distal end of each post comprises:
forming a fourth layer on or over the third layer and the pillar portions of the plurality of posts;
forming a plurality of second openings in the fourth layer, each of the plurality of second openings having a width that is greater than the width of the distal end of the pillar portion and being centered on the pillar portion of a corresponding post; and
forming the solder anchor portion for each post within one of the plurality of second openings.

15. The method of claim 14, wherein forming the plurality of solder balls each on and around the solder anchor portion of the corresponding post comprises:
forming a fifth layer on or over the fourth layer and the solder anchor portion for each post;
forming a plurality of third openings in the fifth layer and in the fourth layer, each of the plurality of third openings having a width that is greater than the width of the solder anchor portion and being centered on the solder anchor portion;
forming a solder shell for each post within one of the plurality of third openings, such that each solder shell covers a distal portion and side portions of the corresponding solder anchor portion for each post;
removing the third, fourth, and fifth layers; and
performing a reflow to melt the solder shell thereby forming the plurality of solder balls disposed on corresponding plurality of solder anchors.

16. The method of claim 14, wherein the plurality of posts is formed on the plurality of conductive pads using semiconductor package manufacturing processes comprising at least one of one or more photoresist film application processes, one or more image transfer processes, one or more pattern transfer processes, one or more material plating processes, one or more photoresist film stripping processes, or one or more reflow processes.

17. The method of claim 13, wherein the package substrate comprises a first layer, a second layer, and a plurality of conductive pads that is formed between the first layer and the second layer, wherein a plurality of openings is formed in the second layer thereby exposing a portion of each of the plurality of conductive pads, wherein:
forming the plurality of posts on the package substrate comprises:
using wire bonding to affix each post to an exposed portion of a corresponding one of the plurality of conductive pads; and
breaking each post to a respective determined length of the pillar portion of the post; and
forming the solder anchor portion on the distal end of each post comprises:
forming a ball tip as the solder anchor portion at the distal end of each post.

18. The method of claim 17, wherein forming the plurality of solder balls each on and around the solder anchor portion of each post comprises:
lowering the package substrate such that the ball tip for each post is dipped into one of a partitioned portion of a tray of molten solder material or a pool of molten solder material, during solder reflow; and
lifting the package substrate away from the one of the partitioned portion of the tray of molten solder material or the pool of molten solder material.

19. The method of claim 17, further comprising:
determining heights of contact points on the PCB based on a scan of a surface of the PCB;
wherein the length of the pillar portion of each post is determined based on the determined heights of corresponding contact points on the PCB;
wherein the length of the pillar portion of each of the plurality of posts is different from that of one or more adjacent posts.

20. A semiconductor device, comprising:
a package substrate comprising one or more bottom layers;
a plurality of posts, each post comprising a proximal end, a pillar portion, and a distal end, each post being coupled at the proximal end to a conductive point on a bottom layer among the one or more bottom layers of the package substrate, each pillar portion having a length extending along its axis between the proximal end and the distal end and a width at a distal end of thereof that is orthogonal to the length;
a solder anchor portion, each solder anchor portion being coupled to the distal end of a corresponding post among the plurality of posts, wherein each solder anchor portion has a width that is larger than the width of the distal end of the pillar portion to which it is coupled; and
a plurality of solder balls, each solder ball being disposed on and around the solder anchor portion of a corresponding post, one or more solder balls among the plurality of solder balls and corresponding one or more posts among the plurality of posts forming conductive interconnects between corresponding conductive points on the package substrate and corresponding contact points on a printed circuit board (“PCB”) device;
wherein the length of the pillar portion of each of the plurality of posts is different from that of one or more adjacent posts, wherein the length of the pillar portion of each post is based on heights of corresponding contact points on the PCB and is not solely based on warpage of the package substrate, wherein the heights of the corresponding contact points on the PCB are determined based on a scan of a surface of the PCB.
